(19) United States
(12) Patent Application Publication
(10) Pub. No.: US 2019/0026629 A1
(43) Pub. Date: Jan. 24, 2019

(54) Systems and Methods for Overshoot Compensation

(71) Applicant: Syntiant, Aliso Viejo, CA (US)

(72) Inventors: Kurt F. Busch, Laguna Hills, CA (US); Jeremiah H. Holleman, III, Davidson, CA (US); Pieter Vorenkamp, Laguna Beach, CA (US); Stephen W. Bailey, Irvine, CA (US)

(73) Assignee: Syntiant, Aliso Viejo, CA (US)

(21) Appl. No.: 16/039,155

(22) Filed: Jul. 18, 2018

Related U.S. Application Data
(60) Provisional application No. 62/534,615, filed on Jul. 19, 2017.

(51) Int. Cl. G06N 3/063; G11C 11/54; G06N 3/04; G06F 8/65; G11C 11/412; G06N 3/08

(52) U.S. Cl. CPC G06N 3/0635; G11C 11/54; G06N 3/08; G06F 8/65; G11C 11/412; G06N 3/049

(57) ABSTRACT

Disclosed herein is a neuromorphic integrated circuit including, in some embodiments, an erasable memory sector including an analog multiplier array of two-quadrant multipliers, the two-quadrant multipliers including cells configured to accept repeated pulses to set weight values for the cells within a tolerance for the weight values of the cells. Also disclosed herein is a method including, in some embodiments, erasing a memory sector of an integrated circuit including an analog multiplier array of two-quadrant multipliers; applying a first set of programming pulses to cells of the two-quadrant multipliers to set weight values for the cells; determining whether or not the weight values of the cells are within a tolerance for the weight values of the cells; and applying a second set of programming pulses to complement cells of the two-quadrant multipliers to compensate for cells not within the tolerance for the weight values of the cell.

### PRIORITY

This application claims the benefit of priority to U.S. Provisional Patent Application No. 62/534,615, filed Jul. 19, 2017, titled “Systems and Methods for Overshoot Compensation,” which is hereby incorporated by reference into this application in its entirety.

### FIELD

Embodiments of the disclosure relate to the field of neuromorphic computing. More specifically, embodiments of the disclosure relate to systems and methods for overshoot compensation.

### BACKGROUND

Traditional central processing units (“CPUs”) process instructions based on “clocked time.” Specifically, CPUs operate such that information is transmitted at regular time intervals. Based on complementary metal-oxide-semiconductor (“CMOS”) technology, silicon-based chips may be manufactured with more than 5 billion transistors per die with features as small as 10 nm. Advances in CMOS technology have been parlayed into advances in parallel computing, which is used ubiquitously in cell phones and personal computers containing multiple processors.

However, as machine learning is becoming commonplace for numerous applications including bioinformatics, computer vision, video games, marketing, medical diagnostics, online search engines, etc., traditional CPUs are often not able to supply a sufficient amount of processing capability while keeping power consumption low. In particular, machine learning is a subsection of computer science directed to software having the ability to learn from and make predictions on data. Furthermore, one branch of machine learning includes deep learning, which is directed at utilizing deep (multilayer) neural networks.

Currently, research is being done to develop direct hardware implementations of deep neural networks, which may include systems that attempt to simulate “silicon” neurons (e.g., “neuromorphic computing”). Neuromorphic chips (e.g., silicon computing chips designed for neuromorphic computing) operate by processing instructions in parallel (e.g., in contrast to traditional sequential computers) using bursts of electric current transmitted at non-uniform intervals. As a result, neuromorphic chips require far less power to process information, specifically, artificial intelligence (“AI”) algorithms. To accomplish this, neuromorphic chips may contain as much as five times as many transistors as a traditional processor while consuming up to 2000 times less power. Thus, the development of neuromorphic chips is directed to provide a chip with vast processing capabilities that consumes far less power than conventional processors. Further, neuromorphic chips are designed to support dynamic learning in the context of complex and unstructured data.

When setting synapses of cells of a neuromorphic chip to their desired weight values, a problem of overshoot exists if one or more of the cells is set with a higher or lower weight value than targeted. That is, all of the cells in the full array must be reset to one extreme weight value before resetting the cells to their target weight values. Provided herein are systems and methods for overshoot compensation.

### SUMMARY

Provided herein is a neuromorphic integrated circuit including, in some embodiments, an erasable memory sector including an analog multiplier array of two-quadrant multipliers, the two-quadrant multipliers including cells configured to accept repeated pulses to set weight values for the cells within a tolerance for the weight values of the cells.

In some embodiments, the weight values correspond to synaptic weight values between neural nodes in a neural network of the neuromorphic integrated circuit.

In some embodiments, input current values multiplied by the weight values provide output current values that are combined to arrive at a decision of the neural network.

In some embodiments, each two-quadrant multiplier of the two-quadrant multipliers has a differential structure configured to allow programmatic compensation for overshoot if any one of two cells is set with a higher or lower weight value than targeted.

In some embodiments, each cell includes a metal-oxide-semiconductor field-effect transistor (“MOSFET”).

In some embodiments, each two-quadrant multiplier of the two-quadrant multipliers is bias free.

In some embodiments, the neuromorphic integrated circuit is configured for one or more application specific standard products (“ASSPs”) selected from keyword spotting, speaker identification, one or more audio filters, gesture recognition, image recognition, video object classification and segmentation, and autonomous vehicles including drones.

Provided herein is a method including, in some embodiments, erasing a memory sector of an integrated circuit including an analog multiplier array of two-quadrant multipliers; applying a first set of programming pulses to cells of the two-quadrant multipliers to set weight values for the cells; determining whether or not the weight values of the cells are within a tolerance for the weight values of the cells; and applying a second set of programming pulses to complement cells of the two-quadrant multipliers to compensate for cells not within the tolerance for the weight values of the cells.

In some embodiments, the integrated circuit is a neuromorphic integrated circuit. The weight values for the cells correspond to synaptic weight values between neural nodes in a neural network of the neuromorphic integrated circuit.

In some embodiments, applying the programming pulses is through a cloud-based firmware update of the neuromorphic integrated circuit.

In some embodiments, the method further includes compensating for cross-talk between adjacent cells, the cross talk resulting from a programming pulse of the first set of programming pulses intended for a target cell that partially programs an adjacent cell.

In some embodiments, compensating for the cross-talk includes monitoring a decrease in pulse width as a current weight value for the adjacent cell and a target weight value for the adjacent cell becomes smaller.

In some embodiments, the method further includes repeatedly applying programming pulses to the cells of the two-quadrant multipliers until meeting the tolerance for the weight values of the cells.

Provided herein is a method including, in some embodiments, erasing a memory sector of a neuromorphic integrated circuit, wherein the memory sector includes an analog multiplier array of two-quadrant multipliers arranged in a number of layers; applying a first set of programming pulses to cells of the two-quadrant multipliers to set initial weight values for the cells, the weight values corresponding to synaptic weight values between neural nodes in a neural network of the neuromorphic integrated circuit; and applying a second set of programming pulses to complement cells of the two-quadrant multipliers to compensate for cells not within the tolerance for the weight values of the cells.

In some embodiments, applying the programming pulses is through a cloud-based firmware update of the neuromorphic integrated circuit.

In some embodiments, applying the programming pulses includes applying the programming pulses to MOSFETs of the cells.

In some embodiments, the method further includes compensating for cross-talk between adjacent cells, wherein the cross-talk results from a programming pulse of the first set of programming pulses intended for a target cell that partially programs an adjacent cell.

In some embodiments, compensating for the cross-talk includes monitoring a decrease in pulse width as a current weight value for the adjacent cell and a target weight value for the adjacent cell becomes smaller.

In some embodiments the erasing sets all weight values to their maximum value and applying the first set of programming pulses or the second set of programming pulses reduces the weight values. An algorithm operates with polarities reversed as needed.

In some embodiments, if a weight value of a target cell of the cells is too high, then a programming pulse of the second set of programming pulses is applied to a complement cell commensurate with at least a difference between a target weight value of the target cell and an amount the target weight value is out of tolerance to compensate for overshoot.

In some embodiments, if a weight value of a target cell of the cells is too low, then a programming pulse of the second set of programming pulses is applied to a complement cell commensurate with at least a difference between a target weight value of the target cell and an amount the target weight value is out of tolerance to compensate for overshoot.

In some embodiments, the method further includes a reading step; and a programming step including applying the first set of programming pulses, the first set of programming pulses, or both. The reading step and the programming step are performed in batches, thereby reducing time required to switch between reading and programming modes of the neuromorphic integrated circuit.

### DRAWINGS

Embodiments of this disclosure are illustrated by way of example and not by way of limitation in the figures of the accompanying drawings, in which like references indicate similar elements and in which:

FIG. 1 provides a schematic illustrating a system for designing and updating neuromorphic integrated circuits (“ICs”) in accordance with some embodiments.

FIG. 2 provides a schematic illustrating an analog multiplier array in accordance with some embodiments.

FIG. 3 provides a schematic illustrating an analog multiplier array in accordance with some embodiments.

FIG. 4 provides a schematic illustrating a bias-free, two-quadrant multiplier of an analog multiplier array in accordance with some embodiments.

FIG. 5A provides a schematic illustrating a method of setting weight values in an analog multiplier array in accordance with some embodiments.

FIG. 5B provides a schematic illustrating a method of setting weight values in an analog multiplier array in accordance with some embodiments.

FIG. 5C provides a schematic illustrating a method of setting weight values in an analog multiplier array in accordance with some embodiments.

### DESCRIPTION

### Terminology

In the following description, certain terminology is used to describe features of the invention. For example, in certain situations, the term “logic” may be representative of hardware, firmware and/or software that is configured to perform one or more functions. As hardware, logic may include circuitry having data processing or storage functionality. Examples of such circuitry may include, but are not limited or restricted to a microprocessor, one or more processor cores, a programmable gate array, a microcontroller, a controller, an application specific integrated circuit, wireless receiver, transmitter and/or transceiver circuitry, semiconductor memory, or combinatorial logic.

The term “process” may include an instance of a computer program (e.g., a collection of instructions, also referred to herein as an application). In one embodiment, the process may be included of one or more threads executing concurrently (e.g., each thread may be executing the same or a different instruction concurrently).

The term “processing” may include executing a binary or script or launching an application in which an object is processed, wherein launching should be interpreted as placing the application in an open state and, in some implementations, performing simulations of actions typical of human interactions with the application.

The term. “object” generally refers to a collection of data, whether in transit (e.g., over a network) or at rest (e.g., stored), often having a logical structure or organization that enables it to be categorized or typed. Herein, the terms “binary file” and “binary” will be used interchangeably.

The term “file” is used in a broad sense to refer to a set or collection of data, information or other content used with a computer program. A file may be accessed, opened, stored, manipulated or otherwise processed as a single entity, object or unit. A file may contain other files and may contain related or unrelated contents or no contents at all. A file may also have a logical format, and/or be part of a file system having a logical structure or organization of plural files. Files may have a name, sometimes called simply the “filename,” and often appended properties or other metadata. There are many types of files, such as data files, text files, program files, and directory files. A file may be generated by a user of a computing device or generated by the computing device. Access and/or operations on a file may be mediated by one or more applications and/or the operating system of a computing device. A filesystem may organize the files of the computing device of a storage device. The filesystem may enable tracking of files and enable access of those files. A filesystem may also enable operations on a file. In some embodiments the operations on the file may include file creation, file modification, file opening, file reading, file writing, file closing, and file deletion.

Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps or acts are in some way inherently mutually exclusive.

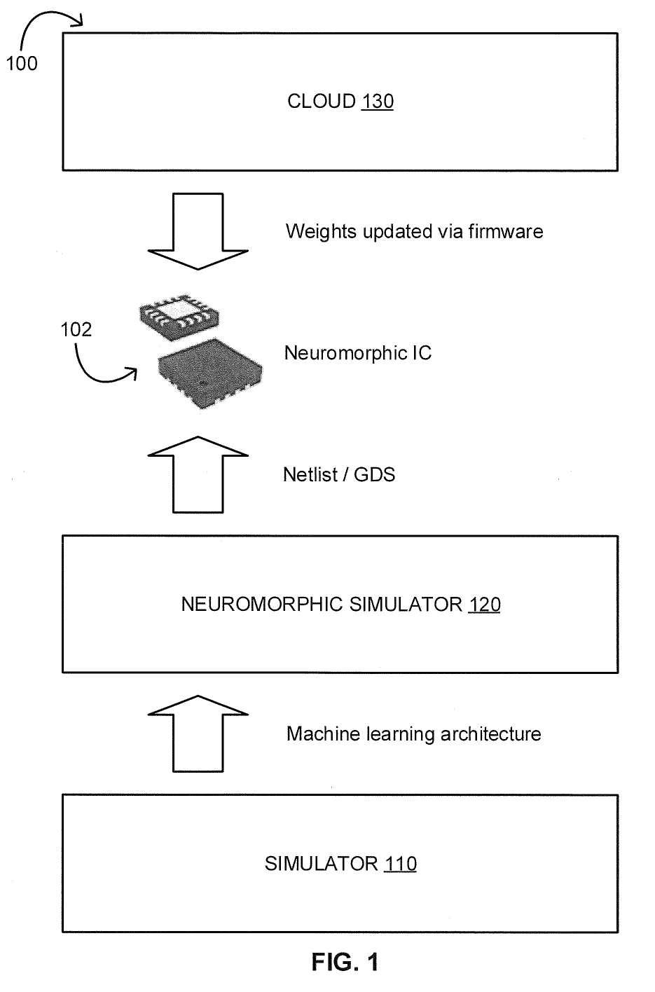

Referring now to FIG. 1, a schematic illustrating a system 100 for designing and updating neuromorphic ICs is provided in accordance with some embodiments. As shown, the system 100 can include a simulator 110, a neuromorphic synthesizer 120, and a cloud 130 configured for designing and updating neuromorphic ICs such as neuromorphic IC 102. As further shown, designing and updating neuromorphic ICs can include creating a machine learning architecture with the simulator 110 based on a particular problem. The neuromorphic synthesizer 120 can subsequently transform the machine learning architecture into a netlist directed to the electronic components of the neuromorphic IC 102 and the nodes to which the electronic components are connected. In addition, the neuromorphic synthesizer 120 can transform the machine learning architecture into a graphic database system (“GDS”) file detailing the IC layout for the neuromorphic IC 102. From the netlist and the GDS file for the neuromorphic IC 102, the neuromorphic IC 102, itself, can be fabricated in accordance with current IC fabrication technology. Once the neuromorphic IC 102 is fabricated, it can be deployed to work on the particular problem for which it was designed. While the initially fabricated neuromorphic IC 102 can include an initial firmware with custom synaptic weights between the nodes, the initial firmware can be updated as needed by the cloud 130 to adjust the weights. Being as the cloud 130 is configured to update the firmware of the neuromorphic IC 102, the cloud 130 is not needed for everyday use.

Neuromorphic ICs such as the neuromorphic IC 102 can be up to 100× or more energy efficient than graphics processing unit (“GPU”) solutions and up to 280× or more energy efficient than digital CMOS solutions with accuracies meeting or exceeding comparable software solutions. This makes such neuromorphic ICs suitable for battery-powered applications.

Neuromorphic ICs such as the neuromorphic IC 102 can be configured for ASSPs including, but not limited to, keyword spotting, speaker identification, one or more audio filters, gesture recognition, image recognition, video object classification and segmentation, or autonomous vehicles including drones. For example, if the particular problem is one of keyword spotting, the simulator 110 can create a machine learning architecture with respect to one or more aspects of keyword spotting. The neuromorphic synthesizer 120 can subsequently transform the machine learning architecture into a netlist and a GDS file corresponding to a neuromorphic IC for keyword spotting, which can be fabricated in accordance with current IC fabrication technology. Once the neuromorphic IC for keyword spotting is fabricated, it can be deployed to work on keyword spotting in, for example, a system or device.

Neuromorphic ICs such as the neuromorphic IC 102 can be deployed in toys, sensors, wearables, augmented reality (“AR”) systems or devices, mobile systems or devices, appliances, Internet of things (“IoT”) devices, or hearables.

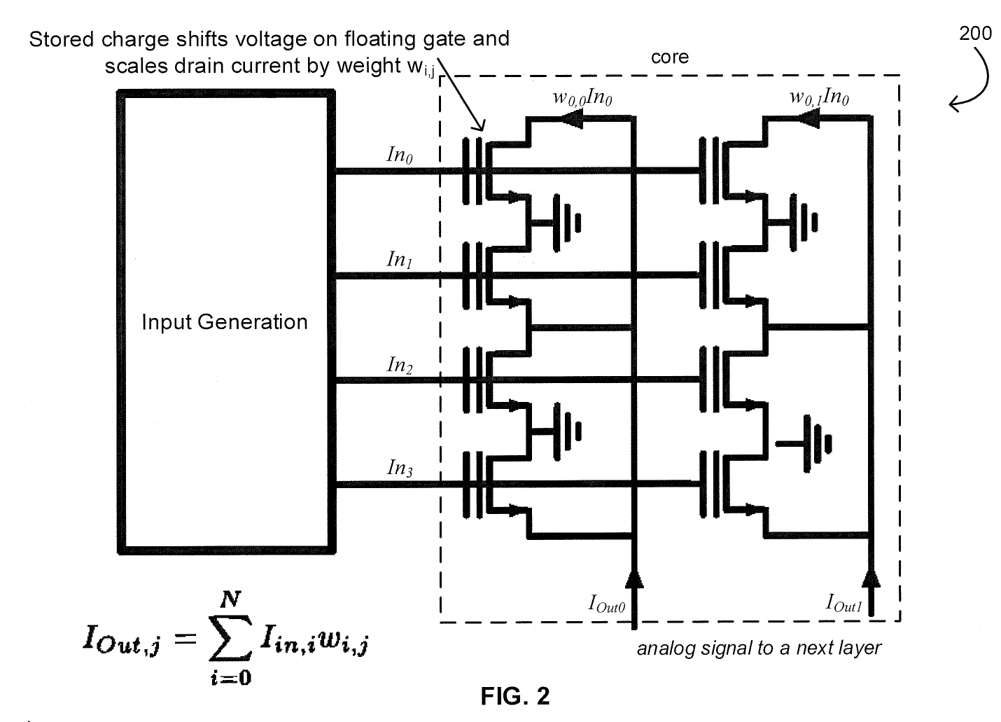

Referring now to FIG. 2, a schematic illustrating an analog multiplier array 200 is provided in accordance with some embodiments. Such an analog multiplier array can be based on a digital NOR flash array in that a core of the analog multiplier array can be similar to a core of the digital NOR flash array. That said, at least select and read-out circuitry of the analog multiplier array are different than a digital NOR array. For example, output current is routed as an analog signal to a next layer rather than over bit lines going to a sense-amp/comparator to be converted to a bit. Word-line analogs are driven by analog input signals rather than a digital address decoder. Furthermore, the analog multiplier array 200 can be used in neuromorphic ICs such as the neuromorphic IC 102.

Since the analog multiplier array 200 is an analog circuit, input and output current values can vary in a continuous range instead of simply on or off. This is useful for storing weights (aka coefficients) of a neural network as opposed to digital bits. In operation, the weights are multiplied by input current values to provide output current values that are combined to arrive at a decision of the neural network.

The analog multiplier array 200 can utilize standard programming and erase circuitry to generate tunneling and erase voltages.

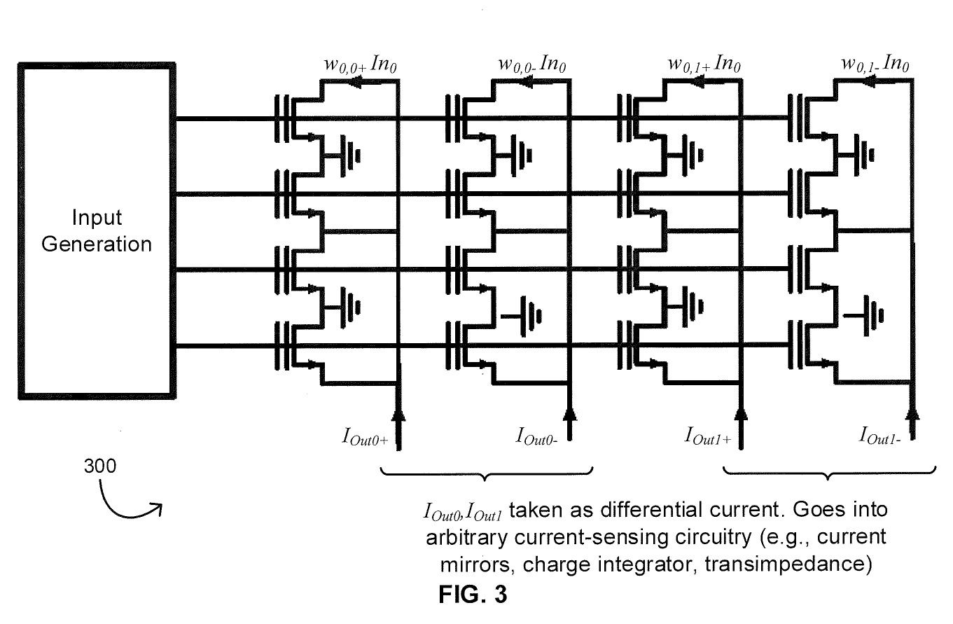

Referring now to FIG. 3, a schematic illustrating an analog multiplier array 300 is provided in accordance with some embodiments. The analog multiplier array 300 can use two transistors (e.g., a positive metal-oxide-semiconductor field-effect transistor [“MOSFET”] and a negative MOSFET) to perform a two-quadrant multiplication of a signed weight (e.g., a positive weight or a negative weight) and a non-negative input current value. If an input current value is multiplied by a positive or negative weight, the product or output current value can respectively be either positive or negative. A positively weighted product can be stored in a first column (e.g., column corresponding to I_{Out0+} in the analog multiplier array 300), and a negatively weighted product can be stored in a second column (e.g., column corresponding to I_{Out0-} in the analog multiplier array 300). The foregoing positively and negatively weighted products or output signal values can be taken as a differential current value to provide useful information for making a decision.

Because each output current from the positive or negative transistor is wired to ground and proportional to the product of the input current value and the positive or negative weight, respectively, the power consumption of the positive or negative transistor is near zero when the input current values or weights are at or near zero. That is, if the input signal values are ‘0,’ or if the weights are ‘0,’ then no power will be consumed by the corresponding transistors of the analog multiplier array 300. This is significant because in many neural networks, often a large fraction of the values or the weights are ‘0,’ especially after training. Therefore, energy is saved when there is nothing to do or going on. This is unlike differential pair-based multipliers, which consume a constant current (e.g., by means of a tail bias current) regardless of the input signal.

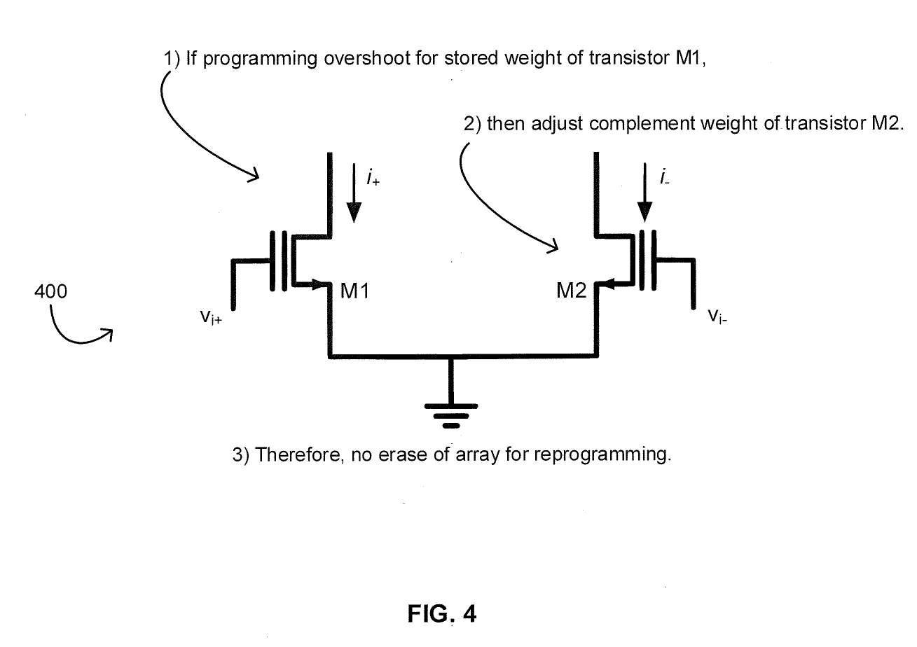

Referring now to FIG. 4, a schematic illustrating a bias-free, two-quadrant multiplier 400 of an analog multiplier array such as the analog multiplier array 300 is provided in accordance with some embodiments. As previously set forth, because each output current from the positive transistor (e.g., M1 of the two-quadrant multiplier 400) or negative transistor (e.g., M2 of the two-quadrant multiplier 400) is proportional to the product of the input current value and the positive or negative weight, respectively, the power consumption of the positive or negative transistor is near zero when the input current values or weights are near zero. This is unlike differential pair-based multipliers, which consume a constant current (e.g., by means of a tail bias current) regardless of the input signal.

When programming a two-quadrant multiplier such as the bias-free, two-quadrant multiplier 400, it is common to erase each programmable cell (e.g., the cell including transistor M1 and the cell including transistor M2) thereof to set the cells to one extreme weight value before setting each of the cells to its target weight value. Extending this to a full array such as the analog multiplier array 300, all of the programmable cells in the full array are set to one extreme weight value before setting each of the cells to its target weight value. When setting the cells to their desired weight values, a problem of overshoot exists if one or more of the cells is set with a higher or lower weight value than targeted. That is, all of the cells in the full array must be reset to the one extreme weight value before resetting the cells to their target weight values. However, the differential structure of each of the bias-free, two-quadrant multipliers of the analog multiplier arrays provided herein allows for compensating such overshoot by programming, thereby obviating the time-consuming process of erasing and resetting all of the cells in an array.

In an example of compensating for overshoot by programming, vᵢ₋ and vᵢ₊ of the two-quadrant multiplier 400 can be erased to set the cells to one extreme weight value. After erasing the cells, if vᵢ₋ is programmed with too large a weight value, vᵢ₊ can be programmed with a larger weight value than initially targeted to compensate for the weight value of vᵢ₋ and achieve the initially targeted effect. Therefore, the differential structure can be exploited to compensate for programming overshoot without having to erase any one or more cells and start over.

Weights can be programmed through a “closed-loop” programming process, in which each programmed weight value of a number of programmed weight values is read or measured in a reading step after applying programming or erase pulses in one or more programming steps in order to ensure that the programmed weight falls within the desired range. In such a method, transition between operational modes of the neuromorphic IC for reading or programming can incur a cost in terms of time or energy dissipation. To minimize the cost effect of such a transition, reading and programming steps can be performed in batches, thereby reducing time required to switch between reading and programming modes of the neuromorphic integrated circuit. That is, some number of cells can be read and the resulting values stored. Then the memory array cab be be set to a programming mode, then programming pulses can be applied to all of those same memory cells.

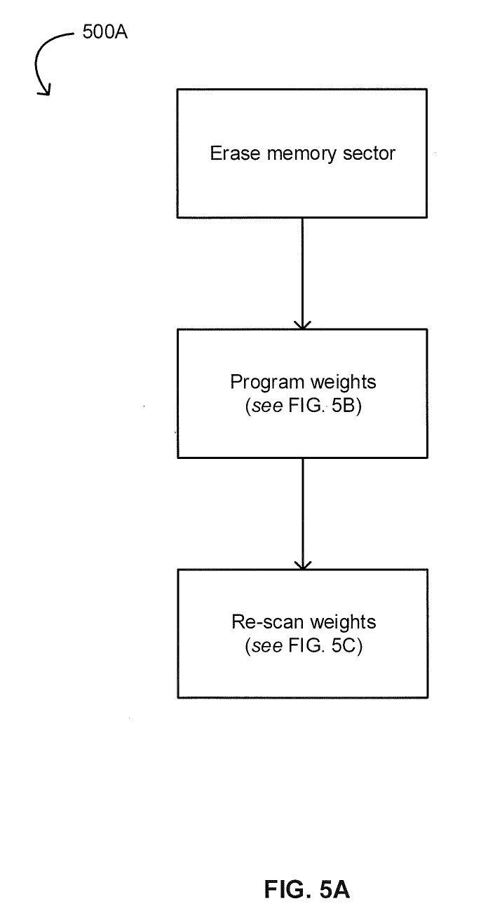

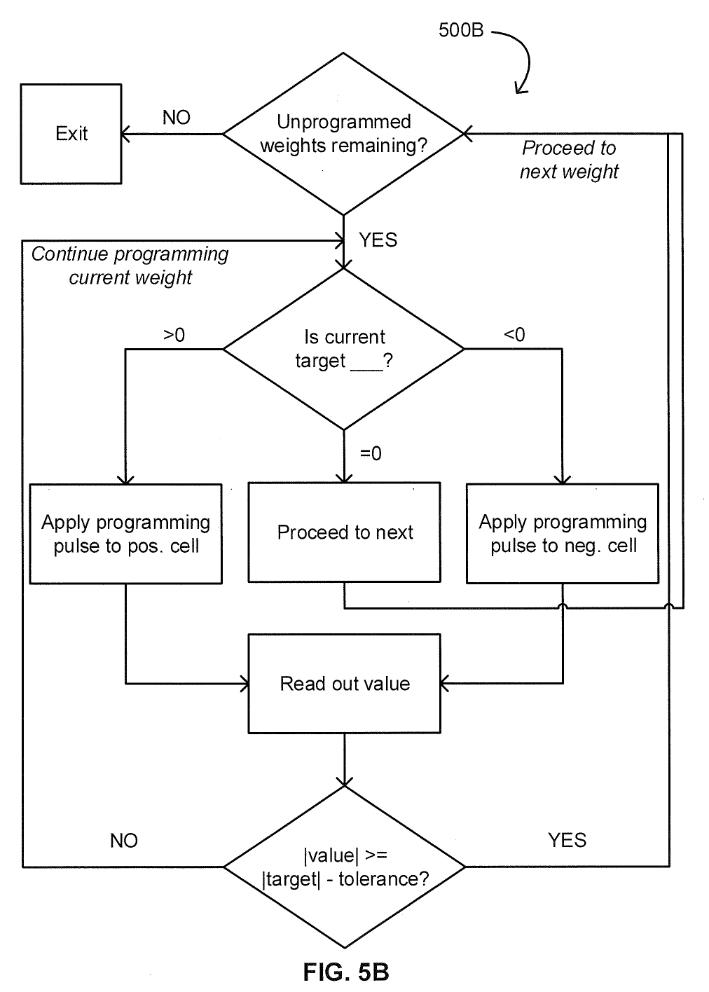

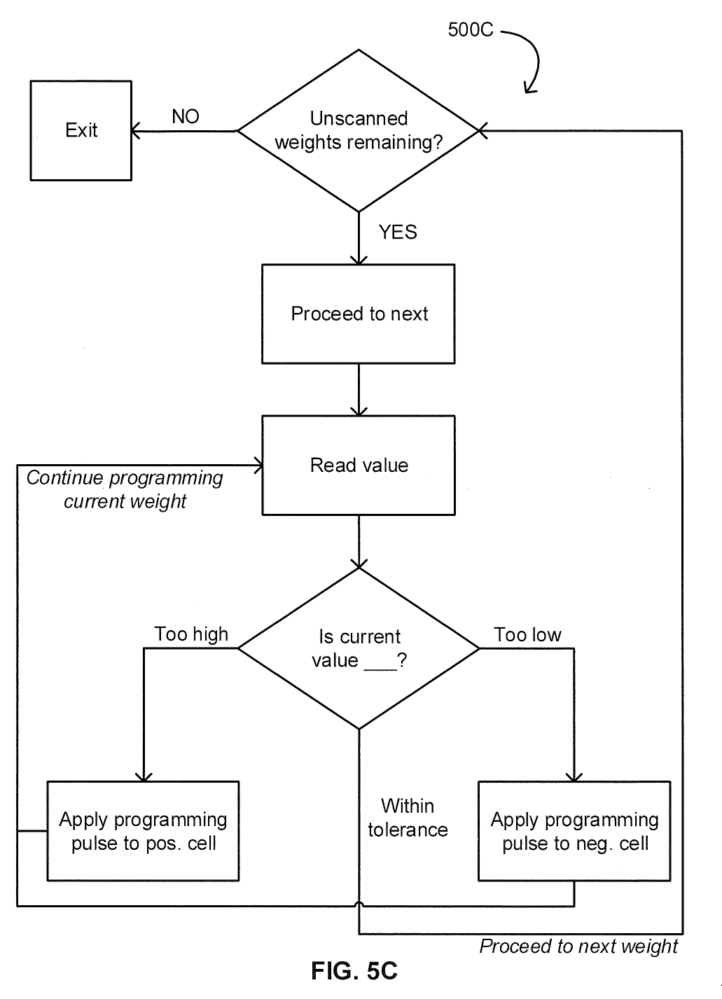

Referring now to FIG. 5A, a schematic illustrating a method 500A of setting weight values in an analog multiplier array is provided in accordance with some embodiments. As shown, the method 500A includes erasing a memory sector of a neuromorphic IC, thereby erasing all of the cells in analog multiplier array; programming weight values for the cells in the analog multiplier array; and rescanning the weight values for the cells in the analog multiplier array.

Referring now to FIG. 5B, a schematic illustrating a method 500B of setting weight values in an analog multiplier array is provided in accordance with some embodiments. As shown, the method 500B includes further detail with respect to the second step of the method 500A: programming weight values. Programming weight values for the cells in accordance with the method 500B includes making a first determination whether or not any unprogrammed cells remain needing weight values. Once the first determination is made, and unprogrammed cells remain, a second determination is made with respect to the weight value to be programmed. If the weight value of a cell is to remain ‘0’ in accordance with the first, cell-erasing step of the method 500A, then a next cell is considered for programming. If the weight value of a cell is to be positive, a pulse is applied to the cell commensurate with the targeted positive weight value of the cell. If the weight value of a cell is to be negative, a pulse is applied to the cell commensurate with the targeted negative weight value of the cell. Regardless of whether the cell is to have a positive or a negative weight value, the next step in the method 500B is to read out the weight value of the cell and subsequently determine if its value is within tolerance. If not, the cell can once again set with the target weight value. Once the weight value of the cell is determined to fall within tolerance, any additional unprogrammed cells remaining in need of weight values are subsequently programmed.

Referring now to FIG. 5C, a schematic illustrating a method 500C of setting weight values in an analog multiplier array is provided in accordance with some embodiments. As shown, the method 500C includes further detail with respect to the third step of the method 500A: rescanning weight values. Rescanning weight values for the cells in accordance with the method 500C includes making a first determination whether or not any unscanned cells remain. Once the first determination is made, and unscanned cells remain, a weight value for a cell of the remaining unscanned cells is read. If the weight value is within tolerance, then another cell is considered for rescanning. If the weight value is too high, then a pulse is applied to a complement cell commensurate with at least a difference between the target weight value and the amount out of tolerance to compensate for the overshoot. For example, if the weight value for vᵢ₋ is too high, then a pulse is applied to vᵢ₊ commensurate with at least a difference between the target weight value for vᵢ₋ and its amount out of tolerance to compensate for the overshoot. Likewise, if the weight value is too low, then a pulse is applied to a complement cell commensurate with at least a difference between the target weight value and the amount out of tolerance to compensate for the overshoot. For example, if the weight value for vᵢ₋ is too low, then a pulse is applied to vᵢ₊ commensurate with at least a difference between the target weight value for and its amount out of tolerance to compensate for the overshoot. Any additional unscanned cells remaining in need of rescanning are subsequently rescanned.

Following on the method 500C, the method can further include a pulse-width adjustment step (e.g., after reading the cells) such that as the difference between a current weight value and a target weight value becomes smaller, the pulse width decreases. The pulse-width adjustment step can be incorporated into the initial programming loop. This allows for a compensation scan to correct for cross-talk (e.g., partial programming of adjacent cells with a pulse intended to program a target cell) in the initial programming loop. The compensation scan can be repeated multiple times in case cross-talk corrupts the weight values.

The foregoing methods enable faster weight value programming because multiple time-consuming erasing and reprogramming steps are obviated. This applies to both global and single-cell erasures. It is noted that while single-cell erasures can be effected in some related technologies, such related technologies use larger, non-standard cells. Such larger, non-standard cells are not as dense or as economical. And, again, such multiple single-cell erasures are time-consuming compared to methods provided herein.

In the foregoing description, the invention is described with reference to specific exemplary embodiments thereof. It will, however, be evident that various modifications and changes may be made thereto without departing from the broader spirit and scope of the invention as set forth in the appended claims.

What is claimed is:

1. A neuromorphic integrated circuit, comprising:
an erasable memory sector including an analog multiplier array of two-quadrant multipliers, the two-quadrant multipliers including cells configured to accept repeated pulses to set weight values for the cells within a tolerance for the weight values of the cells.

2. The neuromorphic integrated circuit of claim 1, wherein the weight values correspond to synaptic weight values between neural nodes in a neural network of the neuromorphic integrated circuit.

3. The neuromorphic integrated circuit of claim 2, wherein input current values multiplied by the weight values provide output current values that are combined to arrive at a decision of the neural network.

4. The neuromorphic integrated circuit of claim 1, wherein each two-quadrant multiplier of the two-quadrant multipliers has a differential structure configured to allow programmatic compensation for overshoot if any one of two cells is set with a higher or lower weight value than targeted.

5. The neuromorphic integrated circuit of claim 4, wherein each cell includes a metal-oxide-semiconductor field-effect transistor (“MOSFET”).

6. The neuromorphic integrated circuit of claim 4, wherein each two-quadrant multiplier of the two-quadrant multipliers is bias free.

7. The neuromorphic integrated circuit of claim 1, wherein the neuromorphic integrated circuit is configured for one or more application specific standard products (“ASSPs”) selected from keyword spotting, speaker identification, one or more audio filters, gesture recognition, image recognition, video object classification and segmentation, and autonomous vehicles including drones.

8. A method, comprising:
erasing a memory sector of an integrated circuit, the memory sector including an analog multiplier array of two-quadrant multipliers;
applying a first set of programming pulses to cells of the two-quadrant multipliers to set weight values for the cells;
determining whether or not the weight values of the cells are within a tolerance for the weight values of the cells; and
applying a second set of programming pulses to complement cells of the two-quadrant multipliers to compensate for cells not within the tolerance for the weight values of the cells.

9. The method of claim 8, wherein the integrated circuit is a neuromorphic integrated circuit, and wherein the weight values for the cells correspond to synaptic weight values between neural nodes in a neural network of the neuromorphic integrated circuit.

10. The method of claim 9, wherein applying the programming pulses is through a cloud-based firmware update of the neuromorphic integrated circuit.

11. The method of claim 8, further comprising:
compensating for cross-talk between adjacent cells, the cross talk resulting from a programming pulse of the first set of programming pulses intended for a target cell that partially programs an adjacent cell.

12. The method of claim 11, wherein compensating for the cross-talk includes monitoring a decrease in pulse width as a current weight value for the adjacent cell and a target weight value for the adjacent cell becomes smaller.

13. The method of claim 8, further comprising:
repeatedly applying programming pulses to the cells of the two-quadrant multipliers until meeting the tolerance for the weight values of the cells.

14. A method, comprising:
erasing a memory sector of a neuromorphic integrated circuit, the memory sector including an analog multiplier array of two-quadrant multipliers arranged in a number of layers;
applying a first set of programming pulses to cells of the two-quadrant multipliers to set initial weight values for the cells, the weight values corresponding to synaptic weight values between neural nodes in a neural network of the neuromorphic integrated circuit; and
applying a second set of programming pulses to complement cells of the two-quadrant multipliers to compensate for cells not within the tolerance for the weight values of the cells.

15. The method of claim 14, wherein applying the programming pulses includes applying the programming pulses to metal-oxide-semiconductor field-effect transistors (“MOSFETs”) of the cells.

16. The method of claim 14, further comprising:
compensating for cross-talk between adjacent cells, the cross talk resulting from a programming pulse of the first set of programming pulses intended for a target cell that partially programs an adjacent cell, wherein compensating for the cross-talk includes monitoring a decrease in pulse width as a current weight value for the adjacent cell and a target weight value for the adjacent cell becomes smaller.

17. The method of claim 14, wherein the erasing sets all weight values to their maximum value and applying the first set of programming pulses or the second set of programming pulses reduces the weight values.

18. The method of claim 14, wherein if a weight value of a target cell of the cells is too high, then a programming pulse of the second set of programming pulses is applied to a complement cell commensurate with at least a difference between a target weight value of the target cell and an amount the target weight value is out of tolerance to compensate for overshoot.

19. The method of claim 14, wherein if a weight value of a target cell of the cells is too low, then a programming pulse of the second set of programming pulses is applied to a complement cell commensurate with at least a difference between a target weight value of the target cell and an amount the target weight value is out of tolerance to compensate for overshoot.

20. The method of claim 14, further comprising:
a reading step; and
a programming step including applying the first set of programming pulses, the first set of programming pulses, or both, wherein the reading step and the programming step are performed in batches, thereby reducing time required to switch between reading and programming modes of the neuromorphic integrated circuit.
